(19) United States
(12) Patent Application Publication
(10) Pub. No.: US 2018/0216230 A1
(43) Pub. Date: Aug. 2, 2018

(54) METHOD FOR PECVD DEPOSITION OF A GRAPHENE-BASED LAYER ON A SUBSTRATE

(71) Applicant: Fraunhofer-Gesellschaft zur Förderung der angewandten Forschung e.V., Munich (DE)

(72) Inventors: Katrin WALD, Dresden (DE); Matthias FAHLAND, Dresden (DE); Steffen GÜNTHER, Dresden (DE); Nicolas SCHILLER, Stolpen OT Helmsdorf (DE)

(73) Assignee: Fraunhofer-Gesellschaft zur Förderung der angewandten Forschung e.V., Munich (DE)

(21) Appl. No.: 15/743,833

(22) PCT Filed: Jul. 13, 2016
(86) PCT No.: PCT/EP2016/066584

§ 371 Date: Jan. 11, 2018

(30) Foreign Application Priority Data
Jul. 14, 2015 (DE) 10 2015 111 351

(51) Int. Cl. C23C 16/50; C23C 14/06; C23C 16/26

(52) U.S. Cl. CPC C23C 16/50; C23C 16/26; C23C 14/0605

(57) ABSTRACT

A method for depositing a graphene-based layer on a substrate by means of chemical vapor deposition is provided in which at least one hydrocarbon is introduced into a vacuum chamber as a starting material for a chemical reaction and, concurrently, a plasma is formed inside the vacuum chamber. In this case, at least one magnetron is used to generate the plasma, where the magnetron comprises at least one target of a material comprising at least one catalytically active metal selected from the group of chemical elements having the atomic numbers 21 to 30, 39 to 48, 57, 72 to 80 and 89; and where the sputtering of the target is set in such a way that the fraction of target particles, embedded in the graphene-based layer, is less than 1 at %.

### CROSS-REFERENCE TO RELATED APPLICATIONS

This application is a 371 nationalization of international patent application PCT/EP2016/066584 filed Jul. 13, 2016, the entire contents of which are hereby incorporated by reference, which in turn claims priority under 35 USC § 119 to Germany patent application 10 2015 111 351 filed Jul. 14, 2015.

### BRIEF DESCRIPTION OF THE DRAWINGS

FIG. 1 shows a schematic representation of a coating apparatus that is suitable for carrying out the method according to the invention.

### DETAILED DESCRIPTION

The invention relates to a method for depositing a graphene-based layer on a substrate by means of chemical vapor phase deposition (also known as chemical vapor deposition, abbreviated as CVD). In this case a plasma is used to assist the CVD process, so that the method according to the invention belongs to the class of plasma-assisted chemical vapor deposition (also known as plasma enhanced chemical vapor deposition, abbreviated as PECVD).

Graphene is, like diamond, graphite and carbon nanotubes, a modification of the element carbon. As a two-dimensional, honeycomb-like network of sp² hybridized carbon atoms, graphene is the basic building block of graphite, which consists of stacked layers of graphene. Graphene arouses interest due to its unusual physical properties. It is mechanically very stable, has a very high tensile strength, conducts heat more than 10 times better than copper, has a theoretical charge carrier mobility of up to 200,000 cm² V⁻¹S⁻¹, and a graphene monolayer absorbs only 2.3% of the light independently of the wavelength in the visible spectrum.

Owing to these properties of graphene, graphene layers can be used, in addition to many other potential applications, as an alternative to TCO (transparent conductive oxide), such as, for example, ITO (indium tin oxide), as a transparent conductive layer, such as, for example, the production of solar cells, but can also be used in OLED and display applications, especially if the requirements are in terms of a mechanical flexibility.

A variety of methods are known that enable the production of graphene. Graphene nanoplatelets and graphene oxide flakes, i.e., graphene particles having lateral expansions in the nm to μm range, can be synthesized from graphite by means of so-called flaking (also called exfoliation).

Graphene layers can be produced, for example, by means of a thermal decomposition of silicon carbide (SiC). In this case, process temperatures of more than 1,000 degrees Celsius are required, so that the silicon atoms in the uppermost layer evaporate due to the higher vapor pressure, and the remaining carbon atoms form a graphene layer.

GB 2 331 998 A describes methods for the deposition of carbon layers having a graphene content, in which method a carbon target is atomized by means of magnetron sputtering. In embodiments of these methods, another magnetron can be used to atomize and deposit in the carbon layer a target made of a transition metal, which however further reduces the graphene content in the carbon layer.

In another known method, graphene layers are produced by chemical vapor deposition, wherein hydrocarbons, such as, for example, methane, are used as the starting materials for a graphene deposition on metallic substrates at temperatures around 1,000 degrees Celsius. In this case, transition metals, such as Cu, Ni and Co, are used; and these transition metals are used simultaneously as a catalyst and substrate in the CVD process and reduce the required decomposition temperature of the hydrocarbon precursor.

The major disadvantages of the known methods include: (1) the high substrate temperatures around 1,000 degrees Celsius, (2) the metallic catalyst substrates required in this case and that make a subsequent transfer of the graphene layers onto an actual target substrate mandatory, and (3) the high substrate costs in the event SiC wafers are used. The transfer process is technologically complex and generates additional defects in the graphene layer.

Plasma-enhanced CVD methods allow the substrate temperature to be decreased by the plasma-induced dissociation of the hydrocarbon precursor, but continue to use catalytic metal substrates with subsequent transfer of the graphene layers onto the desired target substrate. The plasma excitation is usually carried out by means of microwaves at a frequency of 2.45 GHz (WO 2013/052939 A1, WO 2013/052939 A1) or by means of a high frequency excitation at a frequency of 13.56 MHz (WO 2014/137985 A1).

The completely non-catalytic deposition of graphene layers directly onto the target substrates without complicated transfer processes is already known, but to date it was only possible to deposit nanocrystalline graphene layers of a quality that is significantly reduced compared to the deposition with a catalyst. The achievable layer resistances are significantly above those of graphene layers deposited on metallic catalyst substrates by means of CVD.

DE 34 42 208 A1 discloses methods for producing hard carbon layers in which a gaseous hydrocarbon compound is decomposed in an ionized gas atmosphere by means of a magnetron plasma. In this case, the magnetron is equipped with a target consisting of at least one of the metals tantalum, titanium, chromium and tungsten, wherein first a pure layer of the target material is deposited as an adhesion promoter on a substrate and then the actual carbon layer. Such a deposited carbon layer may also include fractions of graphite.

Furthermore, the approach to incorporate a metallic catalyst, not as a substrate, but rather somewhere else in a CVD process has also been examined [J. Teng et al., Remote Catalyzation for Direct Formation of Graphene Layers on Oxides, Nano Letters 12 (2012) pp. 1379-1384; H. Kim et al., Copper Vapor-Assisted Chemical Vapor Deposition for High-Quality and Metal Free Single-Layer Graphene on Amorphous SiO₂ Substrates, ACS Nano 7 (2013) pp. 6575-658]. However, the high substrate temperatures of 1,000 degrees Celsius, which are still required in this case, and the additional incorporation of the metallic catalyst still limit the spectrum of substrates and, associated therewith, the range of application as well as the industrial implementation of graphene layers that are deposited in this way.

Hence, all of the methods known to date suffer from the disadvantages that these methods cannot deposit large area graphene layers, that these graphene layers require a high process temperature, are extremely energy and cost intensive or are bonded to metallic catalyst substrates that require additional process steps in order to transfer the graphene layers.

### OBJECT OF THE INVENTION

The object of the present invention is to provide a method that is intended for the deposition of graphene-based layers and that can be used to overcome the disadvantages known from the prior art. In particular, the objective to be fulfilled by means of the method of the present invention is to be able to deposit large area graphene-based layers and to be able to integrate said graphene-based layers into existing production processes in an energy efficient and cost-effective manner, as well as depositing said graphene-based layers on a broad spectrum of substrates, in particular, on non-catalytic substrates while maintaining the same high quality. A graphene-based layer in the context of the invention means a carbon layer that includes graphene and/or consists entirely of graphene.

In the method according to the invention, a graphene-based layer is deposited on a substrate by chemical vapor deposition inside a vacuum chamber. In this case, at least one hydrocarbon is admitted into the vacuum chamber as a starting material for a chemical reaction, and a plasma is formed concurrently inside the vacuum chamber. Furthermore, the method of the invention is characterized by the feature that at least one magnetron is used to generate the plasma, wherein the magnetron comprises at least one target of a material comprising at least one metal selected from the group of chemical elements having the atomic numbers 21 to 30, 39 to 48, 57, 72 to 80 and 89.

Metallic elements having the atomic numbers 21 to 30, 39 to 48, 57, 72 to 80 and 89 are good catalysts for a multiplicity of reactions, the catalytic effect of which is apparent from the incompletely filled d-atomic orbitals and/or the formation of intermediate compounds, which promote the reactivity of the precursors. Therefore, the chemical elements having the atomic numbers 21 to 30, 39 to 48, 57, 72 to 80 and 89 are also referred to below as catalytically active metals in the context of the method according to the present invention. In the case of the metals Co, Ni, Cu, Ru, Pd, Ir and Pt, their catalytic effectiveness during the deposition of graphene has already been demonstrated in laboratory tests. The element Cu is particularly suitable as a catalytically active target material, since this element is relatively inexpensive to acquire and technically easy to handle.

When at least one catalytically active metal is used as a target material of a magnetron, two advantages are combined in one technical feature. On the one hand, the magnetron is used to generate a plasma, with which a hydrocarbon is split, and the split components are excited to deposit a layer by chemical deposition. On the other hand, the target material of the magnetron acts catalytically to the effect that the deposited carbon is formed as a graphene. Therefore, the method of the present invention makes it possible to coat also those substrates with graphene that do not have a catalytically active metal in the deposited surface area. In addition, the method of the present invention also allows those large substrate areas to be coated with graphene that are known from the prior art of magnetron PECVD methods for coating substrates with other layer materials.

Another advantage of the method of the present invention is that it can also be carried out at process temperatures below 900 degrees Celsius. In laboratory tests it was even possible to form graphene-based layers at process temperatures below 500 degrees Celsius. Therefore, the method of the present invention allows a broader spectrum of substrates to be coated with graphene than the methods known from the prior art.

Suitable starting materials for the chemical vapor deposition of the inventive method include any and all hydrocarbons that are also used in the prior art CVD methods for the deposition of graphene, such as, for example, methane and/or acetylene.

In order to form a magnetron plasma inside a vacuum chamber, it is necessary also to allow a working gas to pass into the vacuum chamber. For this purpose, the known methods often employ inert gases and preferably argon, in order to achieve as high a sputter removal of the magnetron target as possible. In the case of the method of the present invention, however, the objective is to deposit as pure a graphene layer as possible. The method of the present invention is characterized by depositing, as far as possible, no target particles above, below or inside a graphene-based layer to be produced. The target material used in the method of the present invention is used only as a catalyst, so that the deposited carbon is formed as a graphene. Since it usually cannot be completely prevented during the operation of a magnetron that particles of the magnetron target are atomized and are incorporated in the deposited layer, the objective of the method according to the invention is to set the atomization of the target as a consequence of the magnetron sputtering in such a way that the fraction of target particles, embedded in the graphene-based layer, is at least less than 1 at %. With such a degree of purity, the deposited graphene-based layer may be used in a variety of applications. It should be noted that the objective of the method of the present invention is also no sputter removal of the target, in order to deposit target particles above or below the graphene-based layer.

In an embodiment of the method according to the invention, the atomization of the target due to the magnetron sputtering is set in such a way that the fraction of target particles, embedded in the graphene-based layer, is less than 0.1 at %.

The process steps for setting a magnetron process to the effect that as few target particles as possible are embedded in the deposited layer are known. Thus, for example, the electric power of a magnetron can be reduced and, in so doing, also the sputter removal can be reduced until the fraction of target particles, embedded in the layer, has reached a required value.

In order to reduce the sputter removal and, in so doing, also to reduce the incorporation of target particles into the deposited layer of graphene, in an additional embodiment not only the inert gas argon, but also another inert gas is admitted into the vacuum chamber. Particularly suitable for this purpose is the inert gas helium, the content of which makes up at least 60% of the argon/helium gas mixture inside the vacuum chamber. A very slight sputter removal of the magnetron target is attained when the helium content of the argon/helium gas mixture inside the vacuum chamber is at least 90%.

### Exemplary Embodiment

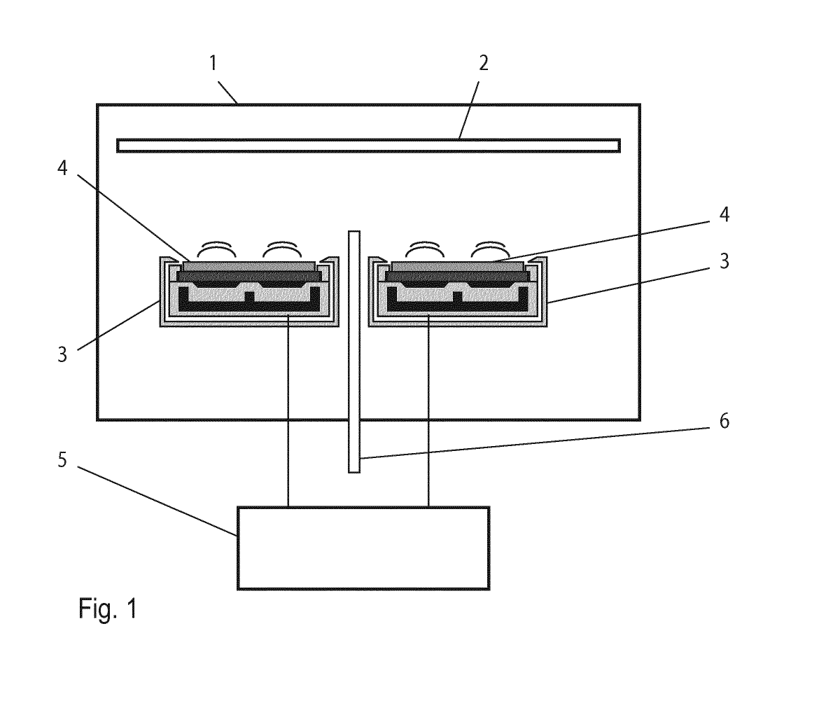

The present invention is explained in greater detail below with reference of one exemplary embodiment. FIG. 1 shows a schematic representation of a coating apparatus that is suitable for carrying out the method according to the invention.

The coating apparatus comprises a vacuum chamber 1, inside which a graphene-based layer is to be deposited on a substrate 2. The substrate 2 is formed as a silicon wafer with a silicon oxide layer that has already been deposited on said wafer, where in this case the graphene-based layer is to be deposited on the silicon oxide layer. Prior to placing the substrate 2 into the vacuum chamber 1, at least the surface of the substrate 2 to be coated was subjected to a cleaning and drying process.

Inside the vacuum chamber 1 there is also a dual magnetron, by means of which a magnetron plasma is formed. The dual magnetron comprises two planar magnetrons 3, each extending into the depth of FIG. 1 and each equipped with a copper target 4. By means of a bipolar pulsing power supply 5, the magnetrons 3 are switched alternately and in opposite directions as the cathode or anode of a magnetron discharge. The bipolar pulsing power supply 5 is usually operated at a frequency in the range of 10 kHz to 100 kHz.

As the starting material for the chemical vapor deposition of a graphene-based layer on the substrate 2, methane is introduced through an inlet 6 into the vacuum chamber 1. Owing to the action of the plasma generated by means of the magnetrons 3, the methane is split and activated in the vacuum chamber, as a result of which a carbonaceous layer is deposited on the substrate 2. During the deposition of the layer, the copper targets 4 act at the same time as a catalyst to the effect that the deposited carbon particles are formed as graphene.

In order to operate the magnetrons 3, a working gas is also introduced, in addition, through the inlet 6 into the vacuum chamber, where in this case the working gas is formed as a gas mixture consisting of 95% helium and 5% argon. The high helium content in the working gas leads to a negligible sputter removal of the magnetron targets 4, so that a graphene-based layer of high purity is deposited on the substrate 2. In the case of the deposited graphene-based layer, a copper content of less than 0.1 at % was determined. By means of Raman spectroscopy it was possible to identify the formation of graphene in the deposited layer. In this case a significantly intense 2D peak with a simultaneously reduced G peak was determined, as compared to an analysis of a graphite layer.

In the case of the inventive layer deposition described above, a dual magnetron, comprising two planar magnetrons, was used solely for illustrative purposes.

As an alternative, the inventive method can also be carried out with any other number of magnetrons, where in this case it is also possible to use magnetrons of any type of construction. The inventive method is also suitable for both the stationary and the dynamic coating of substrates.

Since the term magnetron is also used for apparatuses for generating microwaves, it should be noted at this point that a magnetron, which is involved in the method of the present invention, is always configured as a so-called sputtering magnetron, with which the goal of a sputter removal of an associated target is normally reached.

1. A method comprising depositing a graphene-based layer on a substrate by means of chemical vapor deposition, the depositing comprising:
admitting at least one hydrocarbon is admitted into a vacuum chamber as a starting material for a chemical reaction, and concurrently, and
forming a plasma inside the vacuum chamber, wherein at least one magnetron generates the plasma, wherein the at least one magnetron comprises at least one target of a material comprising at least one catalytically active metal selected from the group of chemical elements having the atomic numbers 21 to 30, 39 to 48, 57, 72 to 80 and 89, and wherein a sputtering of the at least one target is set in such a way that a fraction of target particles embedded in the graphene-based layer is less than 1 at %.

2. The method of claim 1, wherein methane and/or acetylene is/are introduced into the vacuum chamber as a hydrocarbon.

3. The method of claim 1, wherein a substrate is used that has no catalytically active metal in the surface area to be coated.

4. The method of claim 1, wherein the at least one target includes a copper-containing target.

5. The method of claim 1, wherein a process temperature is selected that is less than 900 degrees Celsius.

6. The method of claim 5, wherein a process temperature is selected that is less than 500 degrees Celsius.

7. The method of claim 1, wherein at least one inert gas is introduced into the vacuum chamber.

8. The method of claim 7, wherein an argon/helium gas mixture having a helium content of at least 60% is introduced into the vacuum chamber.

9. (canceled)
